(19) United States
(12) Patent Application Publication
(10) Pub. No.: US 2025/0194194 A1
(43) Pub. Date: Jun. 12, 2025

(54) RADIATION DOPED SEMICONDUCTOR JUNCTIONS

(71) Applicant: The Government of the United States of America, as represented by the Secretary of the Navy, Arlington, VA (US)

(72) Inventors: Marko J. Tadjer, Vienna, VA (US); Karl D. Hobart, Alexandria, VA (US); John M. Gahl, Columbia, MD (US); John D. Brockman, Columbia, MO (US)

(73) Assignees: The Government of the United States of America, as represented by the Secretary of the Navy, Arlington, VA (US); The Curators of the University of Missouri, Columbia, MO (US)

(21) Appl. No.: 18/973,525

(22) Filed: Dec. 9, 2024

Related U.S. Application Data
(60) Provisional application No. 63/607,298, filed on Dec. 7, 2023.

(51) Int. Cl. H10D 62/85; H01L 21/261; H10D 62/60; H10D 62/83; H10D 62/834; H10D 62/854

(52) U.S. Cl. CPC H10D 62/8503; H01L 21/261; H10D 62/60; H10D 62/8303; H10D 62/834; H10D 62/854

(57) ABSTRACT

Implementations of the invention provide semiconductor devices including radiation-doped semiconductor junctions, and methods of making the same. In one embodiments, a method includes: providing a set of adjacent semiconductor layers comprising a first semiconductor layer adjacent a second semiconductor layer different from the first semiconductor layer; exposing the set of adjacent semiconductor layers to thermal neutron radiation, thereby causing a first stable isotope of the first semiconductor layer to convert to a second stable isotope, resulting in a doped first semiconductor layer; and exposing the set of adjacent semiconductor layers to thermonuclear irradiation to cause a third stable isotope of the second semiconductor layer to react, resulting in a doped second semiconductor layer; wherein the doped first semiconductor layer and the doped second semiconductor layer form a homojunction or a heterojunction.

### CROSS-REFERENCE TO RELATED APPLICATIONS

This application is a Nonprovisional of, and claims the benefit of priority under 35 U.S.C. § 119 based on, U.S. Provisional Patent Application No. 63/607,298 filed Dec. 7, 2023, entitled “Ultrawide Bandgap Semiconductor Transmutation Doping and Devices Thereof. The Provisional Application and all references cited herein are hereby incorporated by reference into the present disclosure in their entirety.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case No. 211851-US2.

### BACKGROUND OF THE INVENTION

Aspects of the present invention relate generally to semiconductor manufacturing and, more particularly, to semiconductor devices including radiation-doped semiconductor junctions.

Neutron transmutation doping (NTD) is a well-established technique for commercial production of uniformly doped silicon (Si) boules with a minimum of induced displacement damage at low neutron energies. NTD has also been investigated for doping zinc oxide (Zano) and gallium arsenide (GaAs). Recently, this method has also been investigated for doping gallium nitride (GaN) n-type, since neutron irradiation will produce decay products that can act as dopants in GaN. Specifically, the gallium (Ga) isotopes Ga-70 and Ga-72 will eventually both decay into germanium (Ge) upon interaction with thermal neutrons, and the nitrogen (N) isotope N-14 will decay into the stable boron (B) isotope B-11, as well as making the carbon (C) isotope C-14.

The University of Missouri Research Reactor (MURR) is the largest university reactor in the United States. It has a long history of NTD, providing highly uniform transmutation doped silicon for decades to commercial partners. Recent research efforts at MURR involved the successful transmutation doping of GaN to 10¹⁸ Ge/cm³, resulting in uniform doping unavailable by other methods.

Previous research by others conducting NTD of GaN, utilized reactors which had equal or nearly equal thermal to fast neutron fluxes. At MURR, hanging wedge positions utilized in the pool had a thermal to fast neutron flux ratio of 25:1. In these studies, GaN was doped with Ge to concentrations of 10¹⁶ to 10¹⁸ atoms/cm³. A SIMS analysis demonstrated that the Ge atoms were doped homogenously in the GaN wafer. Compared to previous studies by others, these irradiation positions dramatically reduce radiation damage caused by fast neutron knock-on in GaN irradiation.

It is also known to utilize electron, gamma (Y) or proton irradiation of a silicon substrate, in conjunction with neutron irradiation, in the production of large-area power gate turn-off thyristors to produce recombination centers for adjusting the carrier lifetime. See U.S. Pat. No. 4,806,497. However, there remains a need for reliably doping methods for ultra-wide bandgap semiconductors, such as aluminum nitride (AlN), diamond, and cubic boron nitride (cBN) for use in high-voltage power device applications.

### SUMMARY OF THE INVENTION

In a first aspect of the invention, there is a method including: providing a set of adjacent semiconductor layers comprising a first semiconductor layer adjacent a second semiconductor layer different from the first semiconductor layer; exposing the set of adjacent semiconductor layers to thermal neutron radiation, thereby causing a first stable isotope of the first semiconductor layer to convert to a second stable isotope, resulting in a doped first semiconductor layer; and exposing the set of adjacent semiconductor layers to thermonuclear irradiation to cause a third stable isotope of the second semiconductor layer to react, resulting in a doped second semiconductor layer. The doped first semiconductor layer and the doped second semiconductor layer form a homojunction or a heterojunction.

In embodiments, the first semiconductor layer comprises aluminum nitride (AlN), the first stable isotope is Al-27, and the second stable isotope is silicon-28. In implementations, the second semiconductor layer comprises diamond, the second stable isotope is a carbon (C) isotope C-12, and the reaction creates the unstable carbon (C) isotope C-11, which decays over time to the third stable isotope in the form of B-11. In alternate embodiments, the second semiconductor layer comprises boron (B) doped aluminum nitride (AlN:B), the second stable isotope is a stable B isotope, and the reaction creates a stable beryllium (Be) isotope Be-9. In embodiments, the first semiconductor layer and/or the second semiconductor layer comprise aluminum nitride (AlN) formed by bulk growth methods. In implementations, the method further includes annealing the set of adjacent semiconductor layers.

In embodiments, the method includes forming first and second contacts on the set of adjacent semiconductor layers. The method may further include: fixing the set of adjacent semiconductor layers to a substrate. The substrate may be aluminum nitride (AlN) or aluminum oxide (Al₂O₃). A contact may be formed on a surface of a third semiconductor layer. The third semiconductor layer may be boron (B) doped monocrystalline diamond (NCD:B) or aluminum gallium nitride (AlGaN).

In a second aspect of the invention, there is a semiconductor device including: a set of adjacent semiconductor layers comprising a first thermal neutron doped semiconductor layer adjacent a second thermonuclear radiation-doped semiconductor layer different from the first semiconductor layer; wherein the doped first semiconductor layer and the doped second semiconductor layer form a homojunction or a heterojunction. In implementations, the first semiconductor layer comprises silicon (Si) doped aluminum nitride (AlN). In some embodiments, the second semiconductor layer comprises boron (B) doped diamond. In other embodiments, the second semiconductor layer comprises beryllium (Be) doped aluminum nitride (AlN). The first semiconductor layer and/or second semiconductor layer may be formed by bulk growth methods. In implementations, the device further includes: first and second contacts formed on the set of adjacent semiconductor layers; a substrate; a third semiconductor layer fixed to the set of adjacent semiconductor layers; and a contact formed on a surface of the third semiconductor layer.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1A depicts neutron transmutation doping of aluminum nitride (AlN), containing the AI-27 isotope, to produce AlN doped with silicon (Si) in accordance with embodiments of the invention.

FIG. 1B depicts neutron transmutation doping of aluminum nitride (AlN) doped with boron (B), to produce AlN doped with carbon (C) in accordance with embodiments of the invention.

FIG. 1C depicts neutron transmutation doping of cubic boron nitride (cBN) doped with aluminum, to produce cBN doped with silicon (Si) in accordance with embodiments of the invention.

FIG. 2A depicts thermonuclear radiation doping of aluminum nitride (AlN) doped with boron (B) to produce AlN doped with beryllium (Be), in accordance with embodiments of the invention.

FIG. 2B depicts thermonuclear radiation doping of cubic boron nitride (cBN), containing the B-10 isotope, to produce cBN doped with beryllium (Be) in accordance with embodiments of the invention.

FIG. 2C depicts thermonuclear radiation doping of diamond, containing the C-12 isotope, to produce diamond doped with boron (B) in accordance with embodiments of the invention.

FIG. 2D depicts thermonuclear radiation doping of aluminum nitride (AlN), containing the Al-27 isotope, to produce AlN doped with magnesium (Mg) in accordance with embodiments of the invention.

FIG. 2E depicts thermonuclear radiation doping of aluminum nitride (AlN) containing the AL-27 isotope, to produce AlN doped with silicon (Si), in accordance with embodiments of the invention.

FIG. 3A depicts a doping method utilizing sequential thermal neutron and thermonuclear irradiation to dope adjacent layers, thereby creating a homojunction or heterojunction.

FIG. 3B depicts an exemplary embodiment of the FIG. 3A doping method, where a set of AlN and diamond layers are subjected to sequential thermal neutron doping and thermonuclear irradiation doping to create a heterojunction.

FIG. 3C depicts another exemplary embodiment of the FIG. 3A doping method, where a set of AlN and boron-doped AlN layers are subjected to sequential thermonuclear doping and thermal neutron irradiation doping to create a homojunction.

FIG. 4 depicts targeted doping of a p-type layer utilizing a deuterium beam to generate an n-type doped area.

FIG. 5 shows a flowchart of an exemplary method in accordance with aspects of the present invention.

FIG. 6 is a first exemplary semiconductor device made in accordance with embodiments of the invention.

FIG. 7 is a second exemplary semiconductor device made in accordance with embodiments of the invention.

FIG. 8 is a third exemplary semiconductor device made in accordance with embodiments of the invention.

FIG. 9 is a fourth exemplary semiconductor device made in accordance with embodiments of the invention.

FIG. 10 is a fifth exemplary semiconductor device made in accordance with embodiments of the invention.

FIG. 11 is a sixth exemplary semiconductor device made in accordance with embodiments of the invention.

FIG. 12 is a seventh exemplary semiconductor device made in accordance with embodiments of the invention.

FIG. 13 is an eighth exemplary semiconductor device made in accordance with embodiments of the invention.

FIG. 14 is a ninth exemplary semiconductor device made in accordance with embodiments of the invention.

FIG. 15 is a tenth exemplary semiconductor device made in accordance with embodiments of the invention.

FIG. 16 is an eleventh exemplary semiconductor device made in accordance with embodiments of the invention.

FIG. 17 is a twelfth exemplary semiconductor device made in accordance with embodiments of the invention.

FIG. 18 is a thirteenth exemplary semiconductor device made in accordance with embodiments of the invention.

### DETAILED DESCRIPTION

Aspects of the present invention relate generally to semiconductor manufacturing and, more particularly, to semiconductor devices including radiation-doped semiconductor junctions. Embodiments of the invention provide a method of sequential radiation doping of adjacent semiconductor layers to produce a heterojunction or homojunction. More specifically, a combination of thermal neutron irradiation and thermonuclear irradiation is utilized to sequentially dope adjacent semiconductor layers to produce a heterojunction or homojunction for use in semiconductor devices.

N-type epitaxial AlN doping has been demonstrated via silicon (Si) implantation and annealing. P-type doping of AlN has been demonstrated via a particular mode of moderate-temperature molecular beam epitaxy using beryllium (Be) species, which are highly toxic. However, there is currently no way to produce doped aluminum nitride (AlN) or cubic boron nitride (cBN) crystals with bulk growth techniques. Advantageously, implementations of the invention avoid Be toxicity issues entirely, and enable the uniform doping of substrates produced via either epitaxial or bulk growth techniques.

Furthermore, implementations of the invention exploit the availability of commercial substrates of AlN, which are only available as an insulator due to challenges with doping at high temperatures. Unlike the high temperatures of bulk or epitaxial growth, or ion implantation annealing, NTD irradiation is performed at a moderate temperature using existing aluminum (Al) or boron (B) species at the correct lattice site. As a result, NTD of AlN and cBN according to embodiments of the invention presents a viable route to large-area, uniformly doped crystals of any orientation for power electronics applications.

Currently, conductive AlN substrates are not possible, and doping of epitaxial AlN is difficult to replicate independently. Thick epitaxial layers of AlN are also inherently difficult to dope via ion implantation. The NTD technology described herein is expected to result in n-type epitaxial and bulk AlN and cBN doped in the 10¹⁵-10¹⁷ electrons/cm³ range, similar to that of silicon (Si). Such conductive AlN substrates will greatly reduce the necessity of tens of micrometers of doped epitaxial layers and enable truly vertical AlN power electronics.

### Thermal Neutron Reactions

Embodiments of the invention utilize thermal neutron reactions to dope one or more AlN or cBN layers. In embodiments, AlN could be any ternary or pseudo-binary alloy of AlN of the form AlₓM₁₋ₓN, where x is the composition ratio for Al (0<=x<=1) and M=(Ga, B, In, Sc). In general, a “thermal neutron reaction” is a nuclear reaction where a slow-moving neutron, known as a “thermal neutron,” is absorbed by an atomic nucleus, typically resulting in the emission of gamma radiation and the creation of a new, heavier isotope of the element.

The number of neutron captures per unit volume N in neutron transmutation doping (NTD) is described by the following equation EQ (1), wherein NT is the number of target nuclei per unit volume, σ_{c} is the capture cross section with units of cm², and Φ is the neutron fluence, n/cm²:

$$N = NT σ c Φ . \qquad EQ ( 1 )$$

The cross section represents the probability of interaction between the neutron and the nucleus. Neutron capture reactions occur at higher rates with low energy neutrons because the lower velocity allows greater interaction with the target nuclei. The capture cross section is inversely proportional to the neutron velocity at low energies. Reactor neutrons are parameterized into three groups based on energy: (1) fast neutrons have greater than 100 kiloelectron volts (keV); (2) epithermal neutrons have between 0.5 electron volts (eV) and 100 keV; and (3) thermal neutrons have less than 0.5 eV, with a most probable energy near 0.025 eV. NTD of AlN will occur when the stable aluminum (Al) isotope Al-27 (naturally occurring in the AlN) undergoes a neutron capture reaction with thermal and epithermal neutrons to produce the radioactive isotope Al-28 having a half-life of 2.245 (5) minutes, which decays into the stable Si isotope Si-28. Fast neutrons are unlikely to be captured but cause knock-on damage through elastic scattering, resulting in potential Si donor compensation via deep donor levels (DX centers).

Various mechanisms for transmutation doping of semiconductor materials are discussed herein and may be utilized in implementations of the invention. Exemplary applications are provided as follows.

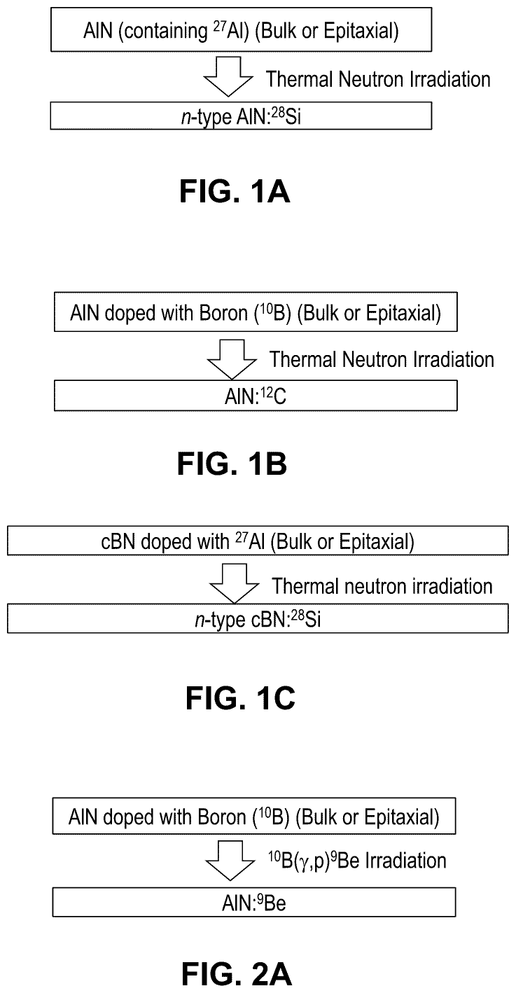

FIG. 1A depicts neutron transmutation doping of aluminum nitride (AlN) to produce AlN doped with silicon (Si), in accordance with embodiments of the invention.

In one embodiment, a method of NTD includes the steps of growing or obtaining AlN (which will naturally include the stable isotope of Al-27), and exposing the AlN to a thermal neutron reaction to transform the Al-27 isotope to the unstable isotope Al-28, which decays into the stable silicon (Si) isotope Si-28 over a period of time, thereby producing Si-doped AlN (AlN:Si). More specifically, the thermal neutron reaction with Al-27 results in neutron capture to produce Al-28, which decays via beta decay with a half-life of 2.245 minutes into Si-28, which is an electron donor in the final n-type AlN:Si product.

FIG. 1B depicts NTD of aluminum nitride (AlN) doped with boron to produce AlN doped with carbon (C), in accordance with embodiments of the invention.

In the embodiment of FIG. 1B, a method of NTD includes the steps of growing or obtaining AlN, doping the AlN with boron (B) utilizing a conventional doping method, where the B naturally includes the stable B-11 isotope, and exposing the B-doped AlN to a thermal neutron reaction to transform the stable B-11 isotope into the unstable isotope B-12, which then decays over a period of time into the stable carbon (C) isotope C-12, thereby producing C-doped AlN (AlN:C). More specifically, the stable isotope B-11 absorbs a thermal neutron to produce the unstable isotope B-12, which then decays into the isotope C-12, primarily via beta decay. Additionally, the stable B isotope B-10 present in the B-doped AlN will absorb a thermal neutron to produce the isotope B-11.

FIG. 1C depicts neutron transmutation doping of cubic boron nitride (cBN) doped with aluminum (Al), to produce cBN doped with silicon (Si) in accordance with embodiments of the invention.

In the embodiment of FIG. 1C, a method of NTD includes the steps of growing or obtaining cBN, doping the cBN with Al utilizing a conventional doping method, where the Al naturally includes the stable Al-27 isotope, and exposing the Al-doped cBN to a thermal neutron reaction to transform the stable Al-27 isotope into the stable isotope Si-28, thereby producing Si-doped cBN (cBN:Si).

### Thermonuclear Reactions

Embodiments of the invention utilize thermonuclear reactions to dope AlN, diamond, and/or cBN layers. In embodiments, AlN could be any ternary or pseudo-binary alloy of AlN of the form AlₓM₁₋ₓN, where x is the composition ratio for Al (0<=x<=1) and M=(Ga, B, In, Sc). In general, a thermonuclear reaction comprises fusion of two light atomic nuclei into a single heavier nucleus by a collision of the two interacting particles at extremely high temperatures, with the consequent release of a relatively large amount of energy. In implementations, thermonuclear reactions may include: (1) bombarding a boron (B) isotope B-10 with a gamma ray (γ), resulting in the emission of a proton (p) and the creation of a beryllium (Be) isotope Be-9 (i.e., ¹⁰B(γ,p)⁹Be) or; (2) bombarding a B-11 isotope with a gamma ray (Y), resulting in the emission of a proton (p) and the creation of a B-10 isotope (i.e., ¹¹B(γ,p)¹⁰Be). In implementations, these thermonuclear reactions are used to generate: B-doped aluminum nitride (AlN:B); B-doped diamond (diamond:B); or Be-doped p-type cubic boron nitride (cBN:Be) via transmutation under gamma irradiation.

Various mechanisms for transmutation doping of semiconductor materials are discussed herein and may be utilized in implementations of the invention. Exemplary applications are provided as follows. Semiconductor materials discussed herein may be grown epitaxially or using bulk growth methods. Advantageously, implementations of the invention allow for Be-doped semiconductors without the need for handling toxic Be doping materials.

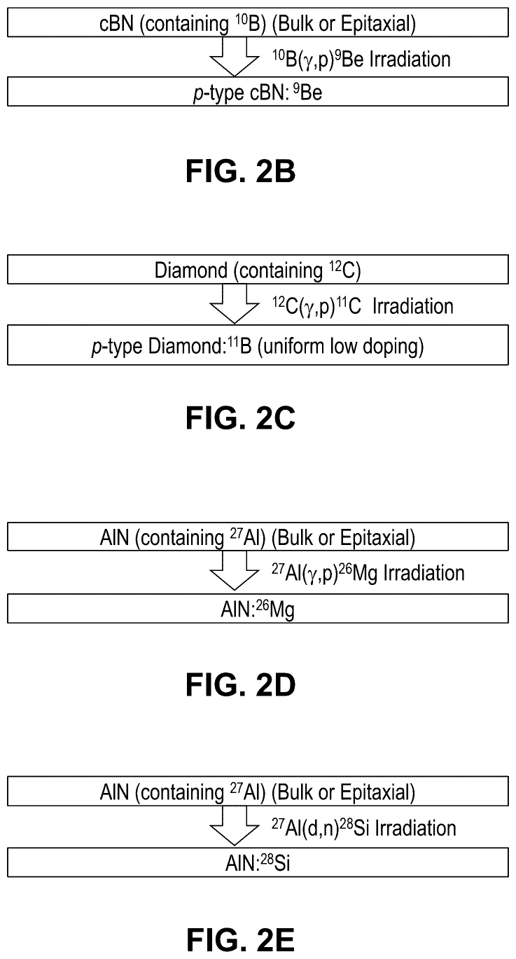

FIG. 2A depicts thermonuclear radiation doping of aluminum nitride (AlN) containing boron (B) to produce AlN doped with beryllium (Be), in accordance with embodiments of the invention.

The embodiment depicted in FIG. 2A includes the steps of obtaining or growing AlN, doping the AlN with boron (B) to produce B-doped AlN (AlN:B) utilizing a conventional doping method, and utilizing the thermonuclear reaction of ¹⁰B(γ,p)⁹Be to cause the AlN:B to become AlN doped with a stable Be isotope Be-9 (i.e., AlN:Be) under gamma irradiation. Specifically, the isotope B-10 in the AlN:B is bombarded with a gamma ray (γ), resulting in the emission of a proton (p), and the creation of the Be-9 isotope. Additionally, irradiation of the AlN:B may cause the thermonuclear reaction ¹¹B(γ,p)¹⁰Be, wherein the isotope B-11 in the AlN:B is bombarded with a gamma ray (Y), resulting in the emission of a proton (p), and the creation of the radioactive isotope Be-10, which has a half-life of 1.39×10⁶ years, and decays to the stable isotope B-10.

FIG. 2B depicts thermonuclear radiation doping of cubic boron nitride (cBN) to produce cBN doped with beryllium (Be), in accordance with embodiments of the invention.

The method of FIG. 2B includes the steps of obtaining or growing cBN, then utilizing thermonuclear reactions of ¹⁰B(γ,p)⁹Be to cause cBN to become a p-type cBN doped with the Be isotope Be-11 (cBN:Be) under gamma irradiation. Specifically, the isotope B-10 in the cBN is bombarded with a gamma ray (γ), resulting in the emission of a proton (p), and the creation of the Be-9 isotope. Additionally, irradiation of the cBN may cause the thermonuclear reaction ¹¹B(γ,p)¹⁰Be, wherein the isotope B-11 in the cBN is bombarded with a gamma ray (Y), resulting in the emission of a proton (p), and the creation of the radioactive isotope Be-10, which has a half-life of 1.39×10⁶ years, and decays to the stable isotope B-10.

FIG. 2C depicts thermonuclear radiation doping of diamond to produce B-doped diamond (diamond:B), in accordance with embodiments of the invention.

The method of FIG. 2C includes the steps of obtaining or growing diamond, then utilizing a thermonuclear reaction of ¹²C(γ,p)¹¹C to cause the diamond to become B-doped diamond. More specifically, in the ¹²C(γ,p)¹¹C reaction, a stable isotope C-12 native to the diamond interacts with a high energy proton (p) to give off a proton (p), becoming unstable C-11, which then decays via positron emission into a stable acceptor isotope dopant B-11, thereby producing B-doped diamond (diamond:B). Advantageously, this method produces a uniform low-doped p-type diamond:B.

FIG. 2D depicts thermonuclear radiation doping of aluminum nitride (AlN) to produce magnesium (Mg) doped AlN (AlN:Mg), in accordance with embodiments of the invention.

In the method of FIG. 2D, AlN is first grown or obtained, then the thermonuclear reaction ²⁷Al(γ,p)²⁶Mg is utilized, wherein a naturally occurring isotope Al-27 in the AlN absorbs a gamma ray photon (γ) and emits a proton (p), thereby transforming into the isotope Mg-26, and producing AlN:Mg.

FIG. 2E depicts thermonuclear radiation doping of aluminum nitride (AlN) by deuterium beam to produce silicon (Si) doped AlN (AlN:Si) in accordance with embodiments of the invention.

Initially, AlN is grown or obtained, which will naturally include the stable isotope Al-27. The embodiment of FIG. 2E utilizes a thermonuclear reaction of ²⁷Al(d,n)²⁸Si, wherein the Al-27 in the AlN is bombarded with a deuterium nucleus (d), resulting in the emission of a neutron (n) and the formation of a silicon (Si) isotope Si-28. This method utilizes a deuterium beam, which can dope n-type a material such as AlN in a specific location near a surface of the AlN material. One advantage of this approach is the possibility of producing an n-type doping area at or near the surface of a p-type doped crystal, potentially resulting in a pn junction formed in a single crystal irradiated via two different methods.

### Isotype or Anisotype Homojunction or Heterojunction Formation

Implementations of the invention result in the formation of heterojunctions or homojunctions. A heterojunction is an interface between two layers or regions of dissimilar semiconductors. In general, heterojunctions can be categorized into two types: isotype and anisotype. The main difference between the two is that isotype heterojunctions have the same conductivity type in both semiconductor layers (i.e., both are doped either p-type or n-type), while anisotype heterojunctions have opposite conductivity types (i.e., one is p-type and one is n-type). In contrast, a homojunction is a semiconductor interface that occurs between two layers of the same or similar semiconductor material. An isotype homojunction is a junction between two parts of a semiconductor that are both either p-type or n-type, but have different free-carrier densities.

In embodiments of the invention, a method for generating an isotype or anisotype homojunction or heterojunction between a first material (AlN:Si, AlN:C, AlN:B, diamond:Be, cBN:Be, cBN:Si, diamond:B, or AlN:Mg) of a first of one of the above-identified irradiation methods and a second material (AlN:Si, AlN:C, AlN:B, diamond:Be, cBN:Be, cBN:Si, diamond:B, or AlN:Mg) of a second of the above-identified irradiation method, includes bonding the first and second materials to produce a composite structure, then sequentially subjecting the composite structure to the first irradiation method then the second irradiation method.

In other embodiments of the invention, a method for generating an isotype or anisotype homojunction or heterojunction between a first material of a first of one of the above-identified irradiation methods (AlN:Si, AlN:C, AlN:B, diamond:Be, cBN:Be, cBN:Si, diamond:B, or AlN:Mg) and a second material (AlN:Si, AlN:C, AlN:B, diamond:Be, cBN:Be, cBN:Si, diamond:B, or AlN:Mg) of a second of the above-identified irradiation method, includes growing the first material on the second material to produce a composite structure, then sequentially subjecting the composite structure to the first irradiation method then the second irradiation method.

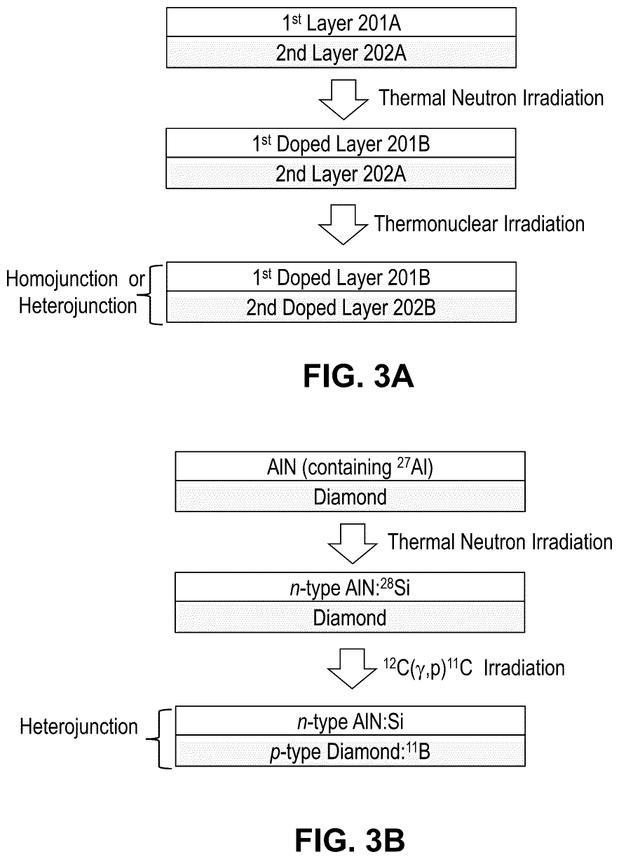

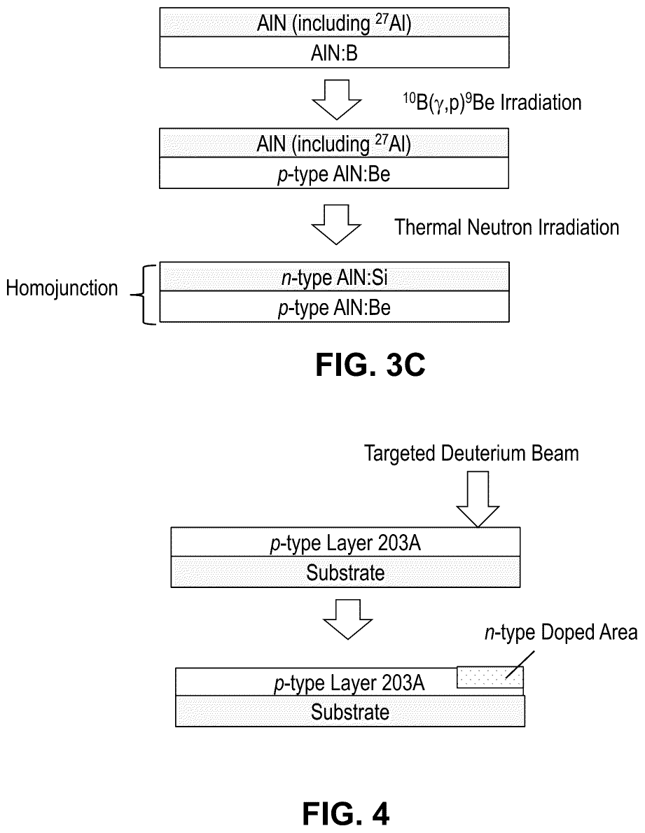

FIG. 3A depicts a doping method utilizing sequential thermal neutron and thermonuclear irradiation to dope adjacent layers to create a homojunction or heterojunction. In the embodiment of FIG. 3A, first and second layers are first subjected to thermal neutron irradiation to dope the first layer, then thermonuclear irradiation to dope the second layer, resulting in a homojunction or a heterojunction. However, it should be understood that the first and second layers could first be subjected to thermonuclear irradiation, then thermal neutron irradiation, resulting in a homojunction or a heterojunction.

In implementations, the above-identified doping strategies are utilized for the creation of pn homo- and heterojunctions of diamond, AlN, cBN, or a combination thereof. For instance, a bonded AlN/diamond composite wafer can be first irradiated with thermal neutrons to produce an n-type AlN:Si with a very small probability of producing the radioactive carbon isotope C-14 in the diamond, followed by gamma irradiation to produce B acceptors on the diamond and some deep Mg acceptors in the AlN, resulting in an n-type AlN:Si and p-type diamond:B heterojunction.

FIG. 3B depicts an exemplary embodiment of the FIG. 3A doping method, where a set of AlN and diamond layers are subjected to sequential thermal neutron and thermonuclear irradiation. The result is a heterojunction of n-type AlN:Si and p-type diamond:B via the mechanisms discussed with respect to FIGS. 1A and 2C.

In the context of semiconductor physics, the equation EQ2 as follows represents a net excess hole concentration p within a material, wherein “NA” is the concentration of acceptor atoms and “ND” is the concentration of donor atoms:

$$p = N A - N D . \qquad EQ2$$

In implementations, a pn or pin homojunction structure is produced through the homoepitaxial growth of AlN:B or a BAIN epitaxial layer on an AlN substrate. Thermal neutron irradiation produces Si donors on both the substrate and epilayer; however, gamma irradiation will generate Be acceptors in the epitaxial layer only. When the Si donor concentration ND is lower than the total concentration of intentional beryllium (Be) acceptors NA, a net excess hole concentration p (p=NA−ND) will result in an p-type doped epitaxial AlN layer on an n-type AlN substrate.

FIG. 3C depicts another exemplary embodiment of the FIG. 3A doping method, where a set of semiconductor layers AlN and boron (B) doped AlN are subjected to sequential thermonuclear and thermal neutron irradiation. The result is a homojunction of n-type AlN:Si and p-type AlN:Be via the mechanisms discussed with respect to FIGS. 1A and 2A.

FIG. 4 depicts targeted doping of a p-type layer utilizing a deuterium beam to generate an n-type doped area. It should be understood that surface doping of a particular target area via a deuterium beam may be implemented in accordance with embodiments of the invention.

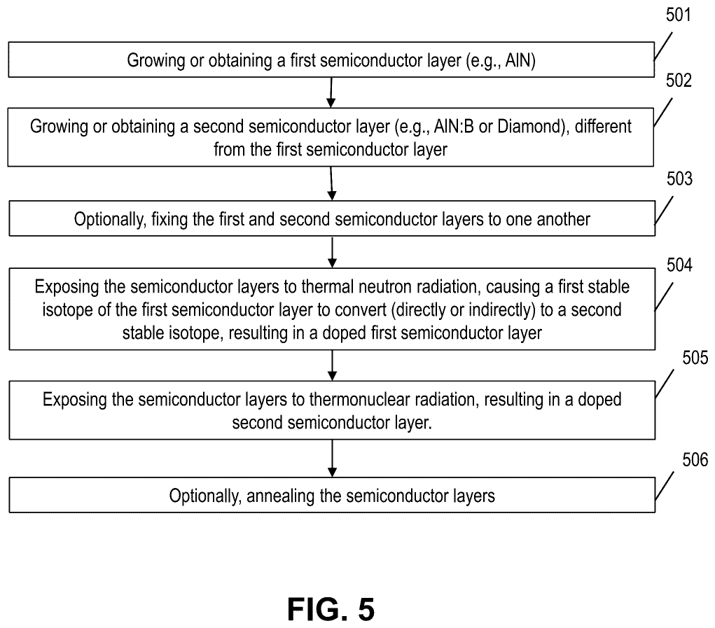

FIG. 5 shows a flowchart of an exemplary method in accordance with aspects of the present invention. The materials and methods of FIG. 3A are referenced in conjunction with FIG. 5.

At step 501, a first semiconductor layer (e.g., 201A) is grown or obtained. In implementation, the first semiconductor layer is an epitaxial layer produced by epitaxial growth methods. Alternatively, the first semiconductor layer may be produced by a bulk growth method. In embodiments, the first semiconductor layer is AlN, which naturally contains the isotope A-27, or cBN.

At step 502, a second semiconductor layer (e.g., 202A) is grown or obtained. In implementation, the second semiconductor layer is an epitaxial layer produced by epitaxial growth methods. Alternatively, the second semiconductor layer may be produced by a bulk growth method. In some embodiments, the second semiconductor layer is grown on the first semiconductor layer. Alternatively, the first semiconductor layer may be grown on the second semiconductor layer. In embodiments, the second semiconductor layer is diamond or B-doped AlN (AlN:B). Conventional doping methods may be utilized to produce the AlN:B in accordance with implementations of the invention.

Optionally, at step 503, the first and second semiconductor layers (e.g., 201A, 202A) are fixed to one another using conventional methods. This step may occur when the first and second semiconductor layers are manufactured separately (e.g., when using bulk growth methods).

At step 504, the first and second semiconductor layers (e.g., 201A, 202A) are exposed to thermonuclear radiation to implement NTD of the first semiconductor layer (e.g., 201A), resulting in a doped first semiconductor layer (e.g., 201B). In one exemplary embodiment, the first semiconductor layer is AlN, and exposing the AlN to thermonuclear radiation results in the process described above with respect to FIG. 1A.

At step 505, the first and second semiconductor layers (e.g., 201B, 202A) are exposed to thermonuclear radiation, resulting in a doped second semiconductor layer (e.g., 202B). In one exemplary embodiment, the second semiconductor layer is diamond, and exposing the diamond to thermonuclear irradiation results in the process described above with respect to FIG. 2C. In another exemplary embodiment, the second semiconductor layer is B-doped AlN (AlN:B), and exposing the AlN:B to thermonuclear irradiation results in the process described above with respect to FIG. 2A. In implementations, steps 504 and 505 result in a heterojunction comprised of n-type AlN:Si and p-type diamond:B, as depicted in FIG. 3B. In other implementations, steps 504 and 505 result in a homojunction comprised of n-type AlN:Si and p-type AlN:Be, as depicted in FIG. 3C.

Optionally, at step 506, the first and second semiconductor layers are annealed using an existing annealing process in order to remove defects introduced by steps 504 and/or 505. This step may be performed after step 504, and/or after step 505.

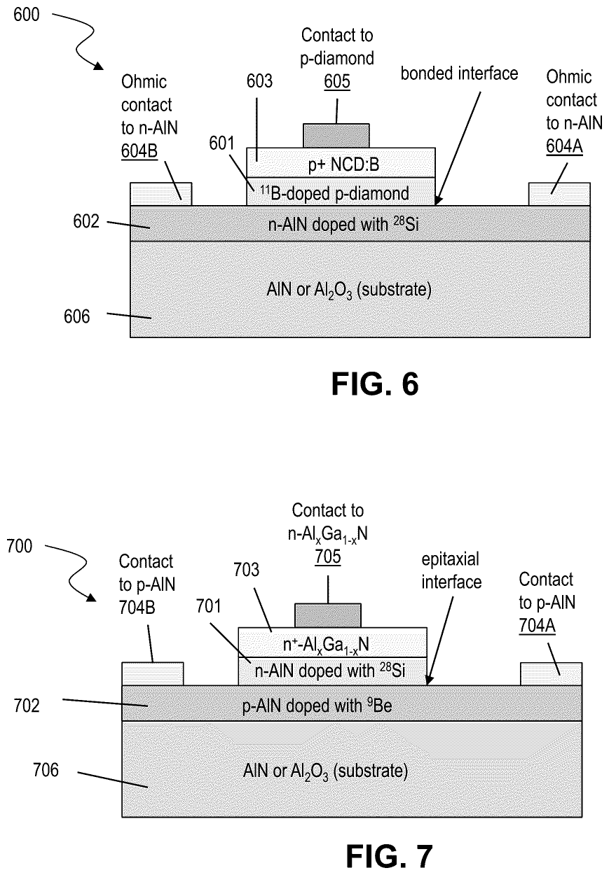

Unless otherwise stated, steps of FIG. 5 may be performed in an order other than the order shown. Moreover, the depiction of the first semiconductor layer 201A as a horizontal layer on top of a second horizontal semiconductor layer 202A is shown for exemplary purposes only, and the layers could be reversed or positioned vertically. Various semiconductor devices could be made using the process of FIG. 5 and the various thermo neutron and thermonuclear radiation doping methods described herein. Some exemplary semiconductor devices are depicted in FIGS. 6-18, and are described below.

FIG. 6 depicts an exemplary heterojunction diode device 600 made in accordance with embodiments of the invention. In implementations, the respective diamond 601 and AlN 602 layers of the heterojunction diode device 600 are doped utilizing the process of FIG. 3B, resulting in a p-type diamond:B layer 601 and an n-type AlN:Si layer 602. In embodiments, the AlN:Si layer has a thickness of 1000 nanometers (nm). The device 600 of FIG. 6 also includes: a p+ type layer 603 of monocrystalline diamond (NCD) doped with boron (NCD:B) with a thickness of 30 nm; a pair of opposing n-type contacts 604A and 604B formed on a surface of the AlN:Si layer 602; a p-type contact 605 formed on the NCD:B layer 603; and a substrate 606 supporting the AlN:Si layer 602, which may be AlN or Al₂O₃.

FIG. 7 depicts an exemplary homojunction diode device 700 made in accordance with embodiments of the invention. In implementations, the AlN layers 701 and 702 of the homojunction diode device are doped utilizing the process of FIG. 3C, resulting in an AlN:Si layer 701 and an AlN:Be layer 702. In implementations, the AlN:Si layer 701 has a thickness of 500 nm. In embodiments, the AlN:Be layer 702 has a thickness of 1000 nm. The device 700 of FIG. 7 also includes: a n+ type layer of AlGaN (AlₓGa₁₋ₓN) 703 (e.g., with a thickness of 30 nm) adjacent a surface of the AlN:Si; a pair of opposing p-type contacts 704A and 704B formed on a surface of the AlN:Be layer 702; an n-type contact 705 formed on a surface of the AlGaN layer 703; and a substrate 706 supporting the AlN:Be layer 702, which may be AlN or Al₂O₃.

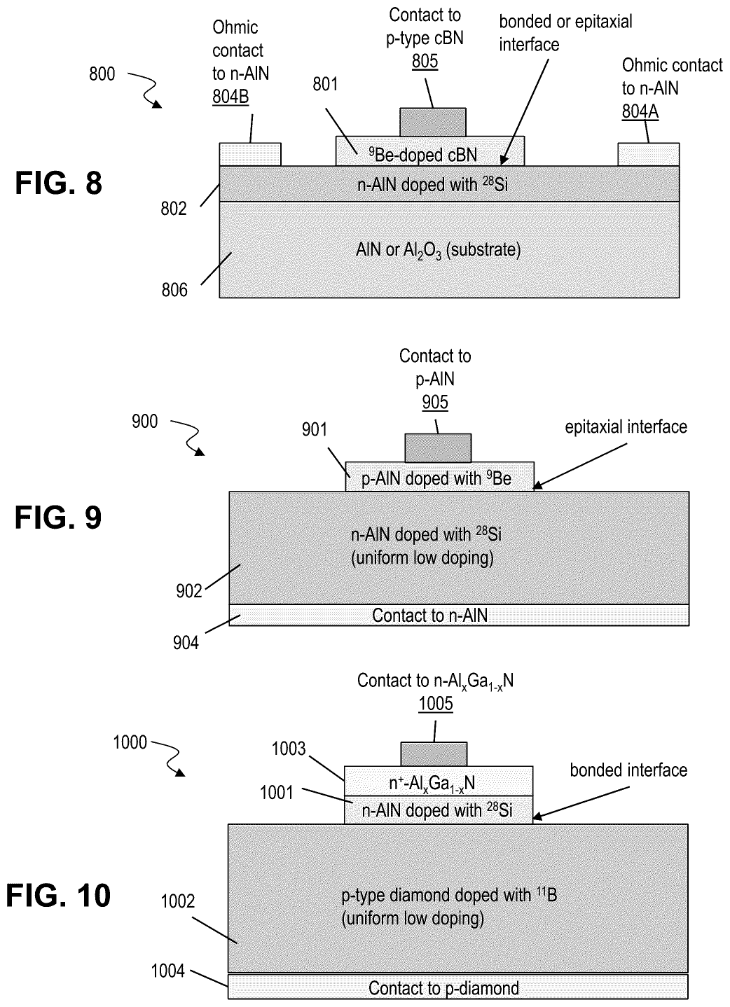

FIG. 8 is another exemplary semiconductor device 800 made in accordance with embodiments of the invention. The semiconductor device 800 includes first and second layers 801 and 802 doped in accordance with processes described above. Specifically, semiconductor device 800 includes a cBN layer 801 doped with the Be isotope Be-9, and an n-type AlN layer 802 doped with the Si isotope Si-28. The device 800 further includes: opposing contacts 804A, 804B formed on a surface of the AlN:Si layer 802; a contact 805 formed on the cBN:Be layer 801; and a substrate 806 supporting the AlN:Si layer 802, which may be AlN or Al₂O₃. In implementations, the interface between the layers 801 and 802 is an epitaxial interface or a bonded interface.

FIG. 9 is another exemplary semiconductor device 900 made in accordance with embodiments of the invention. The semiconductor device 900 includes first and second layers 901 and 902 doped in accordance with processes described above. Specifically, semiconductor device 900 includes an AlN layer 901 doped with the Be isotope Be-9, and an n-type AlN layer 902 doped with the Si isotope Si-28. The device 900 further includes: a contact 904 formed on a bottom surface of the AlN:Si layer 902; and a contact 905 formed on a surface of the AlN:Be layer 901. In implementations, the interface between the layers 901 and 902 is an epitaxial interface.

FIG. 10 is another exemplary semiconductor device 1000 made in accordance with embodiments of the invention. The semiconductor device 1000 includes first and second layers 1001 and 1002 doped in accordance with processes described above. Specifically, semiconductor device 1000 includes a p-type AlN layer 1001 doped with the Si isotope Si-28, and an p-type diamond layer 1002 doped with the B isotope B-11. The device 1000 further includes: an AlGaN (n+-AlₓGa₁₋ₓN) layer 1003 on a surface of the AlN:Si layer 1001; a contact 1004 formed on a bottom surface of the diamond:B layer 1002; and a contact 1005 formed on a surface of the AlGaN layer 1003. In implementations, the interface between the layers 1001 and 1002 is a bonded interface (i.e., layers 1001 and 1002 are bonded to one another).

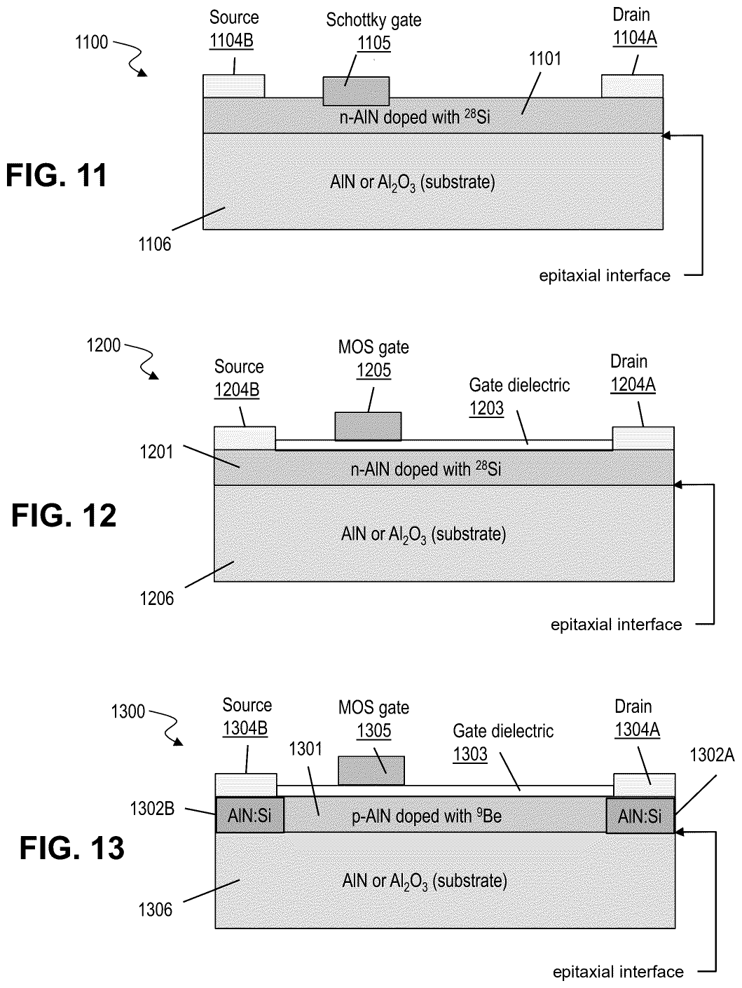

FIG. 11 is another exemplary semiconductor device 1100 made in accordance with embodiments of the invention. The semiconductor device 1100 includes a layer 1101 doped in accordance with processes described above. Specifically, semiconductor device 900 includes an AlN layer 1101 doped with the Si isotope Si-28. The device 1100 further includes: a source 1104B and drain 1104A formed on the AlN:Si layer 1101, a Schottky gate 1105 formed on the AlN:Si layer 1101; and a substrate 1106 supporting the AlN:Si layer 1101, which may be AlN or Al₂O₃. In implementations, the interface between the layers 1101 and 1102 is an epitaxial interface.

FIG. 12 is another exemplary semiconductor device 1200 made in accordance with embodiments of the invention. The semiconductor device 1200 includes a layer 1201 doped in accordance with processes described above. Specifically, semiconductor device 1200 includes an AlN layer 1201 doped with the Si isotope Si-28. The device 1200 further includes: a source 1204B and drain 1204A formed on the AlN:Si layer 1201, a gate dielectric layer 1203 formed on the AlN:Si layer 1201 between the source and drain 1204B, 1204A; a MOS gate 1205 formed on the gate dielectric layer 1203; and a substrate 1206 supporting the AlN:Si layer 1201, which may be AlN or Al₂O₃. In implementations, the interface between the layers 1201 and 1202 is an epitaxial interface.

FIG. 13 is another exemplary semiconductor device 1300 made in accordance with embodiments of the invention. The semiconductor device 1300 includes layers 1301, 1302A, and 1302B doped in accordance with processes described above. Specifically, semiconductor device 1300 includes an AlN layer 1301 doped with the Be isotope Be-9, and AlN layers 1302A, 1302B doped with Si (AlN:Si). The device 1300 further includes: a source 1304B and drain 1304A formed on the AlN:Si layers 1302A, 1302B; a gate dielectric layer 1303 formed on the AlN:Be layer 1301 between the source and drain 1304B, 1304A; a MOS gate 1305 formed on the gate dielectric layer 1303; and a substrate 1306 supporting the AlN:Be layer 1301, which may be AlN or Al₂O₃. In implementations, the interface between the layers 1302A, 1302B and the substrate 1306 is an epitaxial interface.

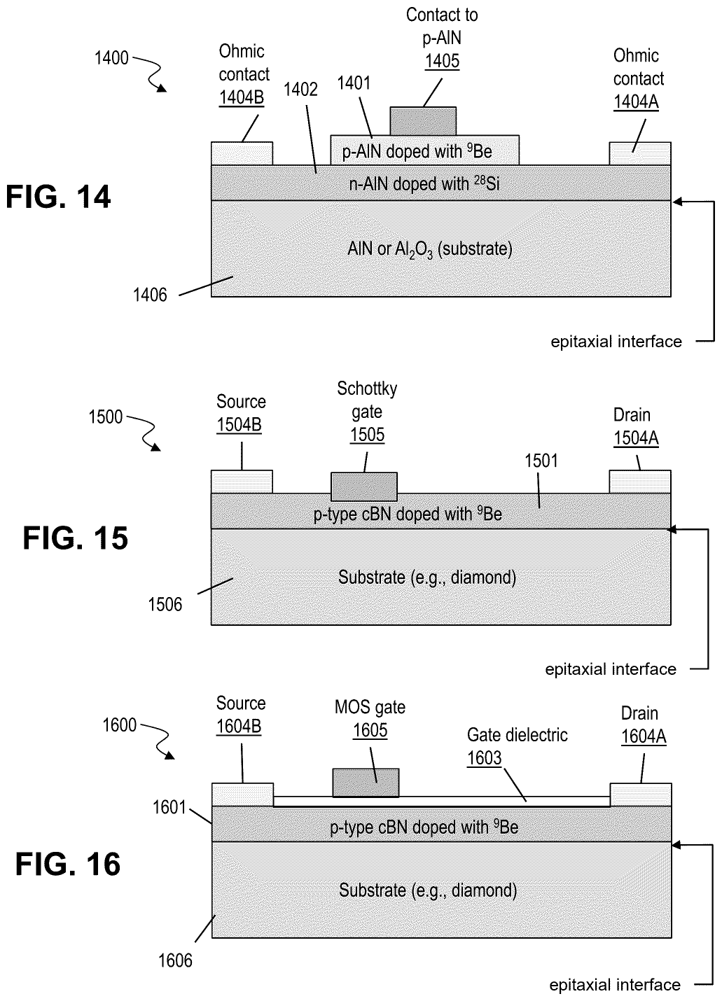

FIG. 14 is another exemplary semiconductor device 1400 made in accordance with embodiments of the invention. The semiconductor device 1400 includes first and second layers 1401 and 1402 doped in accordance with processes described above. Specifically, semiconductor device 1400 includes a p-type AlN layer 1401 doped with the Be isotope Be-9, and an n-type AlN layer 1402 doped with the Si isotope Si-28. The device 1400 further includes: opposing contacts 1404A, 1404B formed on a surface of the AlN:Si layer 1402; a contact 1405 formed on the AlN:Be layer 1401; and a substrate 1406 supporting the AlN:Si layer 1402, which may be AlN or Al₂O₃. In implementations, the interface between the layer 1402 and the substrate 1406 is an epitaxial interface.

FIG. 15 is another exemplary semiconductor device 1500 made in accordance with embodiments of the invention. The semiconductor device 1500 includes a layer 1501 doped in accordance with processes described above. Specifically, semiconductor device 1500 includes a p-type cBN layer 1501 doped with the Be isotope Be-9. The device 1500 further includes: a source 1504B and drain 1504A formed on the cBN:Be layer 1501, a Schottky gate 1505 formed on the cBN:Be layer 1501; and a substrate 1506 supporting the cBN:Be layer 1501, which may be a diamond substrate. In implementations, the interface between the layers 1501 and 1506 is an epitaxial interface.

FIG. 16 is another exemplary semiconductor device 1600 made in accordance with embodiments of the invention. The semiconductor device 1600 includes a layer 1601 doped in accordance with processes described above. Specifically, semiconductor device 1600 includes a cBN layer 1601 doped with the Be isotope Be-9. The device 1600 further includes: a source 1604B and drain 1604A formed on the cBN layer 1601, a gate dielectric layer 1603 formed on the cBN:Be layer 1601 between the source and drain 1604B, 1604A; a MOS gate 1605 formed on the gate dielectric layer 1603; and a substrate 1606 supporting the cBN:Be layer 1601, which may be a diamond substrate In implementations, the interface between the layers 1601 and 1606 is an epitaxial interface.

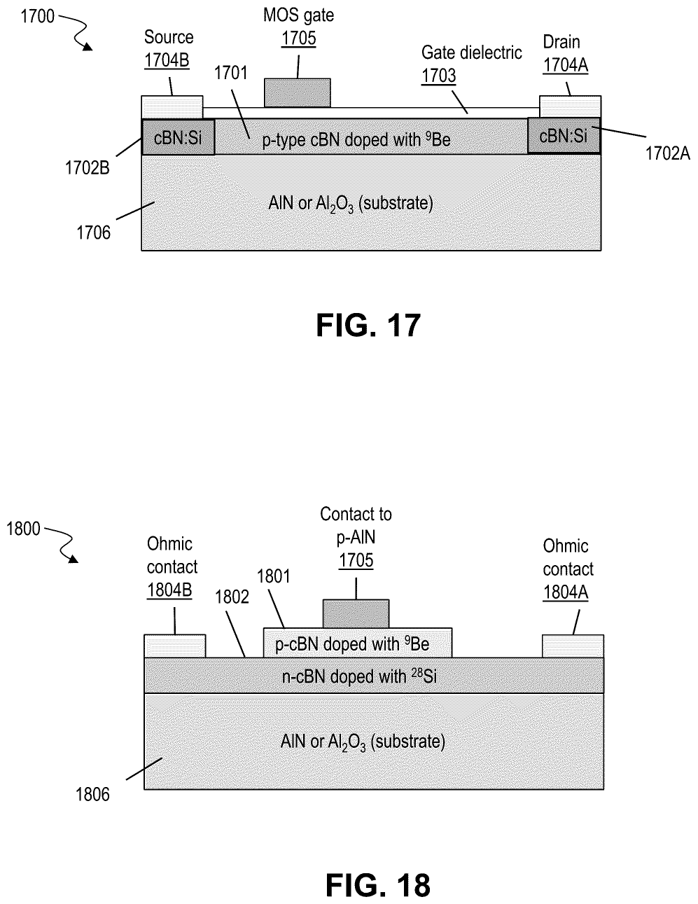

FIG. 17 is another exemplary semiconductor device 1700 made in accordance with embodiments of the invention. The semiconductor device 1700 includes layers 1701, 1702A, and 1702B doped in accordance with processes described above. Specifically, semiconductor device 1700 includes a p-type cBN layer 1701 doped with the Be isotope Be-9, and cBN layers 1702A, 1702B doped with Si (cBN:Si). The device 1700 further includes: a source 1704B and drain 1704A formed on the cBN:Si layers 1702A, 1702B; a gate dielectric layer 1703 formed on the cBN:Be layer 1701 between the source and drain 1704B, 1704A; a MOS gate 1705 formed on the gate dielectric layer 1703; and a substrate 1706 supporting the cBN:Be layer 1701, which may be AlN or Al₂O₃.

FIG. 18 is another exemplary semiconductor device 1800 made in accordance with embodiments of the invention. The semiconductor device 1800 includes first and second layers 1801 and 1802 doped in accordance with processes described above. Specifically, semiconductor device 1800 includes a cBN layer 1801 doped with the Be isotope Be-9, and an n-cBN layer 1802 doped with the Si isotope Si-28. The device 1800 further includes: opposing contacts 1804A, 1804B formed on a surface of the cBN:Si layer 1802; and a substrate 1806 supporting the cBN:Si layer 1802, which may be AlN or Al₂O₃.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of making a semiconductor device comprising:
providing a set of adjacent semiconductor layers comprising a first semiconductor layer adjacent a second semiconductor layer different from the first semiconductor layer;
exposing the set of adjacent semiconductor layers to thermal neutron radiation, thereby causing a first stable isotope of the first semiconductor layer to convert to a second stable isotope, resulting in a doped first semiconductor layer; and
exposing the set of adjacent semiconductor layers to thermonuclear irradiation to cause a third stable isotope of the second semiconductor layer to react, resulting in a doped second semiconductor layer;
wherein the doped first semiconductor layer and the doped second semiconductor layer form a homojunction or a heterojunction.

2. The method of claim 1, wherein the first semiconductor layer comprises aluminum nitride (AlN), the first stable isotope is Al-27, and the second stable isotope is silicon-28.

3. The method of claim 1, wherein the second semiconductor layer comprises diamond, the second stable isotope is a carbon (C) isotope C-12, and the reaction creates the unstable carbon (C) isotope C-11, which decays over time to the third stable isotope in the form of B-11.

4. The method of claim 1, wherein the second semiconductor layer comprises boron (B) doped aluminum nitride (AlN:B), the second stable isotope is a stable B isotope, and reaction creates a stable beryllium (Be) isotope Be-9.

5. The method of claim 1, wherein at least one of the first semiconductor layer and second semiconductor layer comprise aluminum nitride (AlN) formed by bulk growth methods.

6. The method of claim 1, wherein the doped first semiconductor layer and the doped second semiconductor layer form a homojunction.

7. The method of claim 1, wherein the doped first semiconductor layer and the doped second semiconductor layer form a heterojunction.

8. The method of claim 1, further comprising annealing the set of adjacent semiconductor layers.

9. The method of claim 1, further comprising forming first and second contacts on the set of adjacent semiconductor layers.

10. The method of claim 1, further comprising fixing the set of adjacent semiconductor layers to a substrate.

11. The method of claim 10, wherein the substrate is aluminum nitride (AlN) or aluminum oxide (Al₂O₃).

12. The method of claim 11, further comprising fixing a third semiconductor layer to the set of adjacent semiconductor layers.

13. The method of claim 12, further comprising forming a contact on a surface of the third semiconductor layer.

14. The method of claim 12, wherein the third semiconductor layer is boron (B) doped monocrystalline diamond (NCD:B) or aluminum gallium nitride (AlGaN).

15. A semiconductor device comprising:
a set of adjacent semiconductor layers comprising a first thermal neutron doped semiconductor layer adjacent a second thermonuclear radiation-doped semiconductor layer different from the first semiconductor layer;
wherein the doped first semiconductor layer and the doped second semiconductor layer form a homojunction or a heterojunction.

16. The semiconductor device of claim 15, wherein the first semiconductor layer comprises silicon (Si) doped aluminum nitride (AlN).

17. The semiconductor device of claim 15, wherein the second semiconductor layer comprises boron (B) doped diamond.

18. The semiconductor device of claim 15, wherein the second semiconductor layer comprises beryllium (Be) doped aluminum nitride (AlN).

19. The semiconductor device of claim 15, wherein at least one of the first semiconductor layer and second semiconductor layer are formed by bulk growth methods.

20. The semiconductor device of claim 15, further comprising:
first and second contacts formed on the set of adjacent semiconductor layers;
a substrate;
a third semiconductor layer fixed to the set of adjacent semiconductor layers; and
a contact formed on a surface of the third semiconductor layer.
